(19) United States
(12) Patent Application Publication
(10) Pub. No.: US 2024/0302742 A1
(43) Pub. Date: Sep. 12, 2024

(54) PHOTORESIST COMPOSITION INCLUDING PHOTOSENSITIVE POLYMER AND METHOD OF MANUFACTURING INTEGRATED CIRCUIT DEVICE

(71) Applicant: Samsung Electronics Co., Ltd., Suwon-si (KR)

(72) Inventors: Sung Hwan Park, Suwon-si (KR); Sungwon Choi, Suwon-si (KR); Yoonhyun Kwak, Suwon-si (KR); Jeong Ho Mun, Suwon-si (KR); Juhyeon Park, Suwon-si (KR); Songse Yi, Suwon-si (KR); Hogeun Lee, Suwon-si (KR)

(21) Appl. No.: 18/527,056

(22) Filed: Dec. 1, 2023

(30) Foreign Application Priority Data
Mar. 7, 2023 (KR) 10-2023-0030203

(51) Int. Cl. G03F 7/038; C08F 212/14; C08F 220/18; C08F 230/08; H01L 21/027

(52) U.S. Cl. CPC G03F 7/038; C08F 212/30; C08F 220/1807; C08F 230/08; H01L 21/0275

(57) ABSTRACT

A photoresist composition includes a nonionic non-chemically amplified photoresist composition including a photosensitive polymer that includes a first repeating unit having a polarity inversion group and a second repeating unit having a sensitizing group. A method of manufacturing an integrated circuit device includes forming a photoresist film on a feature layer by using the photoresist composition, exposing a first area, which is a portion of the photoresist film, to generate secondary electron from the second repeating unit in the first area and changing a polarity of the first repeating unit by using the secondary electrons in the first area to invert a polarity of the first area, removing a non-exposed area of the photoresist film by using a developer to form a photoresist pattern including the first area, and processing the feature layer by using the photoresist pattern.

### CROSS-REFERENCE TO RELATED APPLICATION

This application is based on and claims priority under 35 U.S.C. § 119 to Korean Patent Application No. 10-2023-0030203, filed on Mar. 7, 2023, in the Korean Intellectual Property Office, the disclosure of which is incorporated by reference herein in its entirety.

### BACKGROUND

In recent years, the downscaling of semiconductor devices has rapidly progressed due to the development of electronics technology. Accordingly, a photolithography process that is advantageous for implementing fine patterns may be required. In particular, it is necessary to develop a technique by which a dissolution contrast for a developer between an exposed area and a non-exposed area of a photoresist film may be improved in a photolithography process for manufacturing an IC device.

### SUMMARY

The present disclosure provides a photoresist composition, which may improve a dissolution contrast for a developer between an exposed area and a non-exposed area of a photoresist film in a photolithography process for manufacturing an integrated circuit (IC) device.

The present disclosure also provides a method of manufacturing an IC device, by which a dimensional precision of a pattern to be formed may be increased by improving a dissolution contrast for a developer between an exposed area and a non-exposed area of a photoresist film in a photolithography process.

In general, innovative aspects of the subject matter described in this specification can be embodied in a nonionic non-chemically amplified photoresist composition including a photosensitive polymer including repeating units represented by Formula 1:

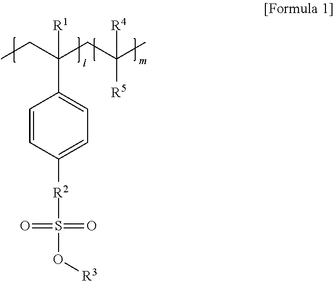

wherein each of R¹ and R⁴ is a hydrogen atom, a substituted or unsubstituted C1-C10 linear or branched alkyl group, a substituted or unsubstituted C2-C10 linear or branched alkenyl group, a substituted or unsubstituted C2-C10 linear or branched alkynyl group, a substituted or unsubstituted C1-C3 alkoxy group, a C6-C18 aryl group, a C6-C18 cycloalkyl group, or a C6-C18 arylalkyl group, R² is a direct bond, a C1-C10 alkylene group, a C1-C10 halogenated alkylene group, a C2-C10 alkenyl group, a C2-C10 halogenated alkenyl group, a C2-C10 alkynyl group, a C2-C10 halogenated alkynyl group, a C3-C20 cycloalkylene group, a C6-C20 arylene group, a C6-C20 halogenated arylene group, a C7-C20 arylalkylene group, or a C7-C20 alkylarylene group, R³ is an unsubstituted C1-C10 linear or branched alkyl group, a C1-C10 linear or branched alkyl group substituted with a fluorine (F) atom, an unsubstituted C2-C10 linear or branched alkenyl group, a C2-C10 linear or branched alkenyl group substituted with a fluorine atom, an unsubstituted C2-C10 linear or branched alkynyl group, a C2-C10 linear or branched alkynyl group substituted with a fluorine atom, an unsubstituted C6-C20 aryl group, a C6-C20 aryl group substituted with a fluorine atom, an unsubstituted C7-C20 arylalkyl group, a C7-C20 arylalkyl group substituted with a fluorine atom, an unsubstituted C7-C20 alkylaryl group, or a C7-C20 alkylaryl group substituted with a fluorine atom, R⁵ is a C6-C30 aryl group including at least one of a hydroxy group and a C1-C5 alkoxy group, and each of 1/(1+m) and m/(1+m) is in a range of 0.05 to 0.95.

In general, in another aspect, there is provided a method of manufacturing an IC device. The method includes forming a photoresist film on a feature layer by using a nonionic non-chemically amplified photoresist composition including a photosensitive polymer. The photosensitive polymer includes a first repeating unit having a polarity inversion group and a second repeating unit having a sensitizing group. A first area, which is a portion of the photoresist film, is exposed to generate secondary electrons from the second repeating unit in the first area, and a polarity of the first repeating unit is changed by using the secondary electrons in the first area to invert a polarity of the first area. A non-exposed area of the photoresist film is removed by using a developer to form a photoresist pattern including the first area. The feature layer is processed by using the photoresist pattern.

### BRIEF DESCRIPTION OF THE DRAWINGS

Examples of the present disclosure will be more clearly understood from the following detailed description taken in conjunction with the accompanying drawings in which:

FIG. 1 is a flowchart of a method of manufacturing an integrated circuit (IC) device; and

FIGS. 2A to 2E are cross-sectional views of a process sequence of a method of manufacturing an IC device.

### DETAILED DESCRIPTION OF THE EMBODIMENTS

The present disclosure relates to a photoresist composition including a photosensitive polymer and a method of manufacturing an integrated circuit (IC) device, and more particularly, to a photoresist composition, which is a nonionic and non-chemically amplified negative photoresist composition that includes a photosensitive polymer including a repeating unit having a polarity inversion group, and a method of manufacturing an IC device by using the photoresist composition.

Hereinafter, examples of the present disclosure will be described in detail with reference to the accompanying drawings. The same reference numerals are used to denote the same elements in the drawings, and repeated descriptions thereof will be omitted.

### Photosensitive Polymer

A photosensitive polymer may include a first repeating unit having a polarity inversion group and a second repeating unit having a sensitizing group.

The photosensitive polymer may be represented by Formula 1:

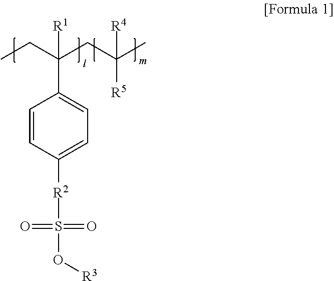

wherein: each of R¹ and R⁴ is a hydrogen atom, a substituted or unsubstituted C1-C10 linear or branched alkyl group, a substituted or unsubstituted C2-C10 linear or branched alkenyl group, a substituted or unsubstituted C2-C10 linear or branched alkynyl group, a substituted or unsubstituted C1-C3 alkoxy group, a C6-C18 aryl group, a C6-C18 cycloalkyl group, or a C6-C18 arylalkyl group, R² is a direct bond, a C1-C10 alkylene group, a C1-C10 halogenated alkylene group, a C2-C10 alkenyl group, a C2-C10 halogenated alkenyl group, a C2-C10 alkynyl group, a C2-C10 halogenated alkynyl group, a C3-C20 cycloalkylene group, a C6-C20 arylene group, a C6-C20 halogenated arylene group, a C7-C20 arylalkylene group, or a C7-C20 alkylarylene group, R³ is an unsubstituted C1-C10 linear or branched alkyl group, a C1-C10 linear or branched alkyl group substituted with a fluorine atom, an unsubstituted C2-C10 linear or branched alkenyl group, a C2-C10 linear or branched alkenyl group substituted with a fluorine atom, an unsubstituted C2-C10 linear or branched alkynyl group, a C2-C10 linear or branched alkynyl group substituted with a fluorine atom, an unsubstituted C6-C20 aryl group, a C6-C20 aryl group substituted with a fluorine atom, an unsubstituted C7-C20 arylalkyl group, a C7-C20 arylalkyl group substituted with a fluorine atom, an unsubstituted C7-C20 alkylaryl group, or a C7-C20 alkylaryl group substituted with a fluorine atom, and R⁵ is a C6-C30 aryl group including at least one of a hydroxy group and a C1-C5 alkoxy group.

In Formula 1, a repeating unit indicated by “1” may be the first repeating unit having the polarity inversion group, and a R³ group included in the first repeating unit may contribute to polarity inversion. In Formula 1, a repeating unit indicated by “m” may be the second repeating unit having the sensitizing group, and secondary electrons may be generated from an R⁵ group included in the second repeating unit due to exposure.

In Formula 1, 1 may be a mole fraction of the first repeating unit and m may be a mole fraction of the second repeating unit. In Formula 1, each of 1/(1+m) and m/(1+m) may be in a range of 0.05 to 0.95.

In Formula 1, when R² is a direct bond, a phenylene group and a sulfur (S) atom of a sulfonate group is directly bonded to each other in Formula 1. As used herein, the “direct bond” may be indicated by “*-*. ”

As used herein, “arylene” may refer to a divalent ring including a portion of a stable monocyclic or polycyclic system, and the divalent ring may refer to a structure having 6 to 20 carbon (C) atoms. In the divalent ring, at least one carbon atom may be substituted with a hetero element-containing group. As used herein, the hetero element-containing group may include an oxygen atom, a nitrogen atom, a halogen element, cyano, thio, silyl, ether, carbonyl, ester, nitro, amino, or a combination thereof. For example, the hetero element-containing group may be —O—, —C(═O)—O—, —O—C(═O)—, —C(═O)—, —O—C(═O)—O—, —C(═O)—NH—, —NH—, —S—, —S(═O)₂—, or —S(═O)₂—O—.

As used herein, unless otherwise defined, the term “substituted” may refer to including at least one substituent, for example, a halogen atom (e.g., a fluorine (F) atom, a chlorine (Cl) atom, a bromine (Br) atom, or an iodine (I) atom), hydroxyl, amino, thiol, carboxyl, carboxylate, ester, amide, nitrile, sulfide, disulfide, nitro, C1 to C20 alkyl, C1 to C20 cycloalkyl, C2 to C20 alkenyl, C1 to C20 alkoxy, C2 to C20 alkenoxy, C6 to C30 aryl, C6 to C30 aryloxy, C7 to C30 alkylaryl, or a C7 to C30 alkylaryloxy group.

Without wishing to be bound by theory, when a photoresist film including the photosensitive polymer having the structure represented by Formula 1 is exposed, secondary electrons may be generated from the R⁵ group included in the second repeating unit indicated by “m” in Formula 1. The generated secondary electrons may be reacted with the R³ group included in the first repeating unit indicated by “1”, and thus, a polarity of the first repeating unit may be inversed from hydrophobicity to hydrophilicity. Accordingly, the solubility in a hydrophobic developer may be reduced.

In some implementations, in Formula 1, R³ may be an aryl group including an electron withdrawing group. As used herein, the term “electron withdrawing group” may indicate that atoms in a covalent bond have a high tendency to attract electrons shared by other atoms. The electron withdrawing group included in R³ may be selected from a halogen atom selected from F, Cl, Br, and I, a heterocyclic group including sulfur (S), a heterocyclic group including nitrogen (N), a nitro group (—NO₂), a trifluoro methyl group (—CF₃), a pentafluoro ethyl group (—C₂F₅), a trifluoromethyl sulfonyl group (—SO₂CF₃), a pentafluoroethyl sulfonyl group (—SO₂C₂F₅), an acetyl group (—COCH₃), an aldehyde group (—CHO), a ketone group (—C(═O)—), a carboxyl group (—CO₂H), an ester group (—CO₂R) (here, R is a C1-C10 alkyl group), and cyano (CN).

In some implementations, in Formula 1, R² may be selected from the following structures, without being limited thereto. In the following structures, “*” denotes a linking site.

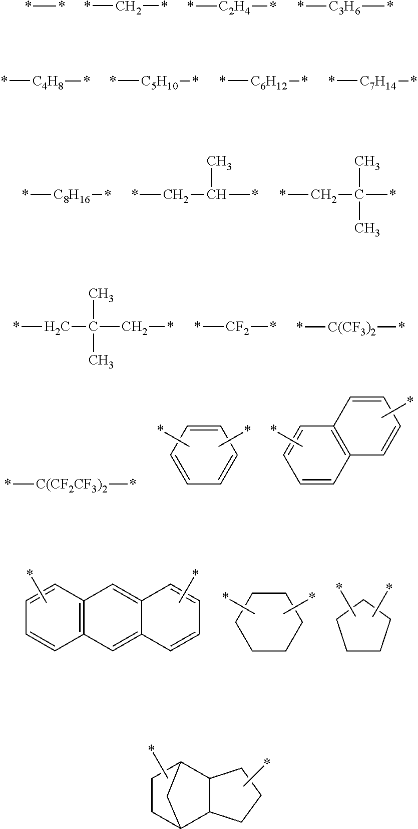

In some implementations, in Formula 1, R³ may have a structure represented by Formula 2:

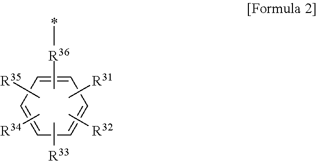

wherein each of R³¹, R³², R³³, R³⁴, and R³⁵ may be a hydrogen atom, a fluorine atom, a linear or branched C1-C10 perfluoroalkyl group, a linear or branched C2-C10 perfluoroalkenyl group, or a linear or branched C2-C10 perfluoroalkynyl group, at least some of R³¹, R³², R³³, R³⁴, and R³⁵ may be the same as each other, and R³⁶ is a C1-C10 perfluoroalkylene group.

In some implementations, in Formula 1, R³ may be selected from the following structures, without being limited thereto. In the following structures, “*” denotes a linking site:

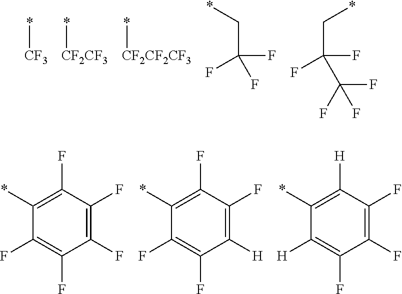

wherein R⁵ may include any one selected from a phenyl group, a naphthyl group, an anthracenyl group, and a pyridinyl group.

In some implementations, R⁵ may have any one structure selected from the following Formulas 3-1, 3-2, 3-3, 3-4, and 3-5.

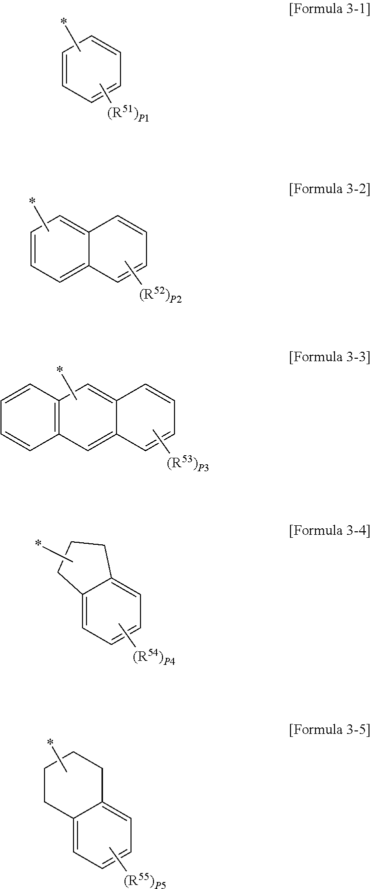

wherein each of R⁵¹, R⁵², R⁵³, R⁵⁴, and R⁵⁵ is a hydroxy group or a C1-C5 alkoxy group, P1 is an integer of 1 to 5, P2 is an integer of 1 to 7, P3 is an integer of 1 to 9, P4 is an integer of 1 to 6, P5 is an integer of 1 to 7, and * is a linking site.

For example, in Formula 1, R⁵ may have any one structure selected from the following structures, without being limited thereto:

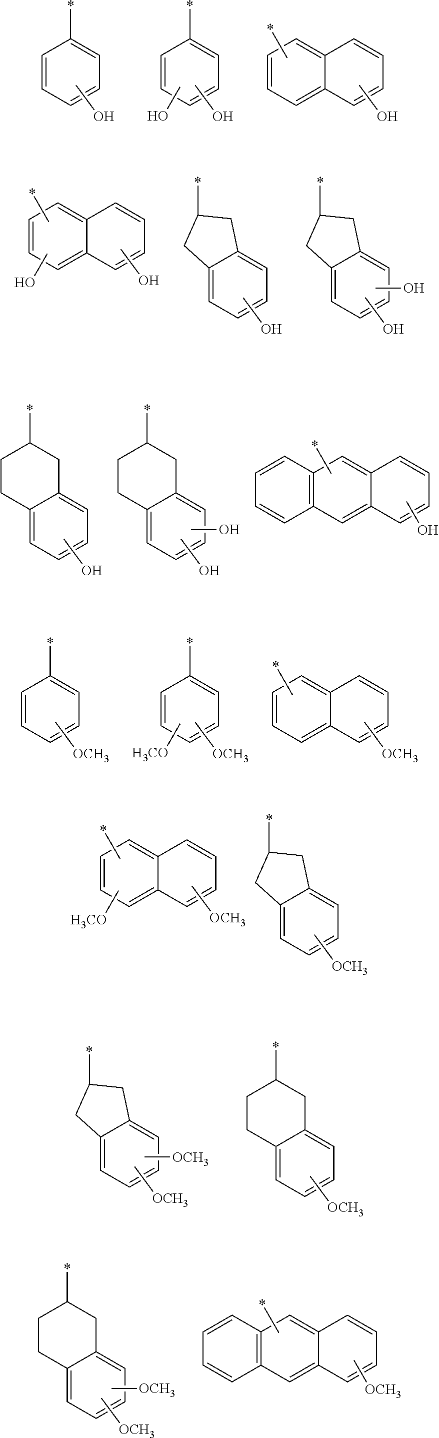

In the structures, * may be a linking site.

In some implementations, in addition to the repeating structures repeated by Formula 1, the photosensitive polymer according to the inventive concept may further include a repeating unit represented by Formula 4:

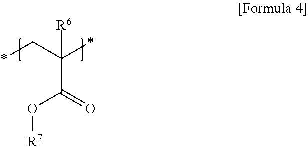

wherein R⁶ is a hydrogen atom, a substituted or unsubstituted C1-C10 linear or branched alkyl group, a substituted or unsubstituted C2-C10 linear or branched alkenyl group, a substituted or unsubstituted C2-C10 linear or branched alkynyl group, a C1-C3 alkoxy group, a C6-C18 aryl group, a C6-C18 cycloalkyl group, or a C6-C18 arylalkyl group, R⁷ is a substituted or unsubstituted C1-C10 linear or branched alkyl group, a substituted or unsubstituted C2-C10 linear or branched alkenyl group, a substituted or unsubstituted C2-C10 linear or branched alkynyl group, a substituted or unsubstituted C3-C30 alicyclic group, a substituted or unsubstituted C6-C20 aryl group, a substituted or unsubstituted C2-C20 heteroaryl group, a substituted or unsubstituted C7-C20 arylalkyl group, a substituted or unsubstituted C7-C20 alkylaryl group, or a substituted or unsubstituted C2-C20 heteroarylalkyl group, and * is a linking site.

As used herein, the repeating unit represented by Formula 4 may be referred to as a third repeating unit. In the photosensitive polymer according to the present disclosure, the third repeating unit of Formula 4 may adjust the molecular weight of the photosensitive polymer, adjust the etching resistance of a photoresist pattern including the photosensitive polymer, and/or additionally adjust the solubility of the photosensitive polymer. When the photosensitive polymer includes the third repeating unit of Formula 4, the third repeating unit may have a mole fraction of about 0.1 to about 0.9 in the photosensitive polymer. In the third repeating unit of Formula 4, R⁷ may or may not be an acid-labile group.

In some implementations, R⁷ may include a hydroxy-containing alicyclic moiety. In some implementations, R⁷ may have any one structure selected from the following structures, without being limited thereto:

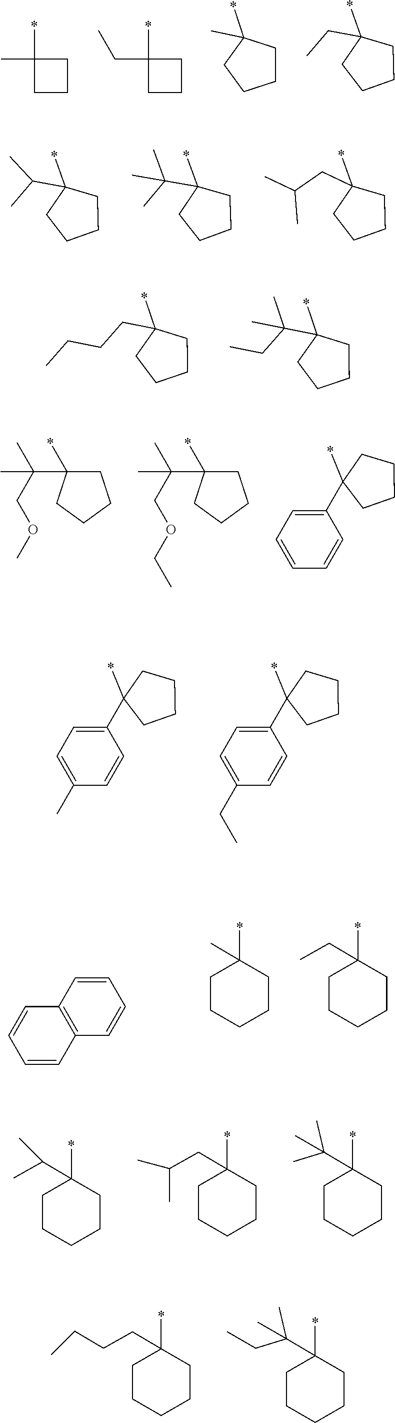

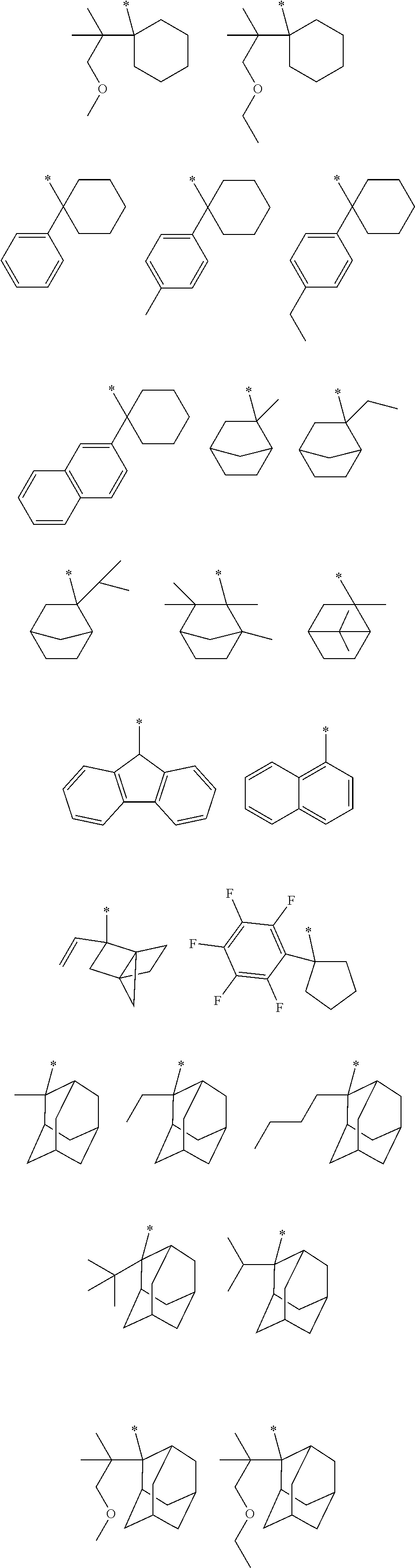

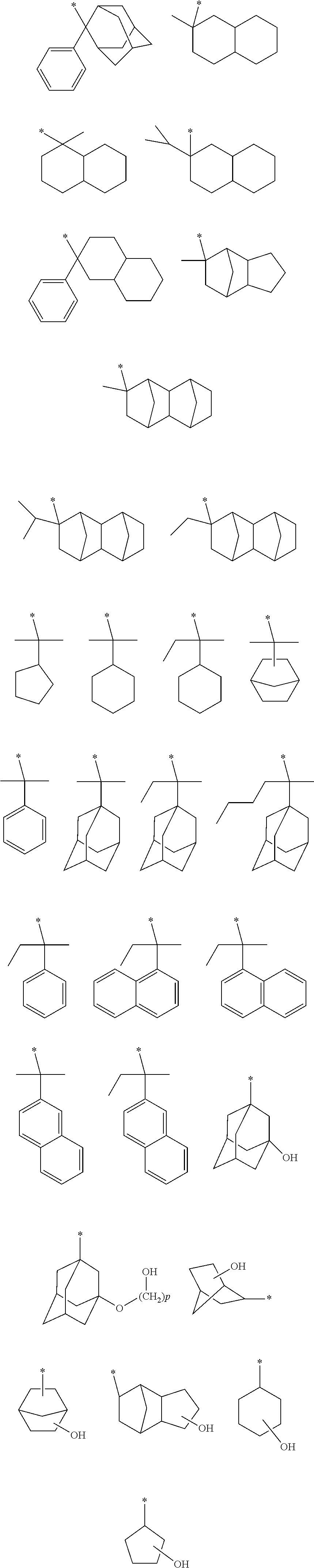

wherein p is an integer of 1 to 10 and * is a linking site.

The photosensitive polymer may have a weight average molecular weight (Mw) of about 1,000 to about 500,000, without being limited thereto.

### Photoresist Composition

A photoresist composition may include a photosensitive polymer, which includes a first repeating unit having a polarity inversion group and a second repeating unit having a sensitizing group, and a solvent.

In some implementations, in the photoresist composition, the photosensitive polymer may include the first repeating unit and the second repeating unit, which are represented by Formula 1. In other embodiments, in the photoresist composition, the photosensitive polymer may further include a third repeating unit of Formula 4. Details of each of Formulas 1 and 4 may be understood with reference to the descriptions herein.

In some implementations, in the photoresist composition, the photosensitive polymer may include at least two first repeating units having different structures from each other, from among first repeating units represented by “1” in Formula 1, or at least two second repeating units having different structures from each other, from among second repeating units represented by “m” in Formula 1. In still other embodiments, in the photoresist composition, the photosensitive polymer may further include at least one third repeating unit (e.g., two or three third repeating units), which is represented by Formula 4 and has different structures.

In some implementations, in the photoresist composition, the photosensitive polymer may include a blend of a photosensitive polymer including at least one first repeating unit and at least one second repeating unit and a polymer including at least one third repeating unit.

In some implementations, in the photoresist composition, the photosensitive polymer may further include at least one of a fourth repeating unit and a fifth repeating unit. The fourth repeating unit may include a (meth)acrylate-based monomer unit having a substituent including a hydroxyl group (—OH). The fifth repeating unit may include a (meth)acrylate-based monomer unit having a protecting group substituted with fluorine.

In some implementations, the photoresist composition includes about 1% to about 60% by weight of the photosensitive polymer based on the total weight of the photoresist composition, without being limited thereto.

In some implementations, the photoresist composition may not include, as a non-chemically amplified resist, a photoacid generator (PAG) configured to generate an acid due to exposure. In some implementations, in the photoresist composition, a polarity of the photosensitive polymer may be changed by changing a structure of the photosensitive polymer without an additional additive, and thus, a photoresist pattern may be formed without an additional annealing process after exposure.

In the photoresist composition, the solvent may include an organic solvent. In embodiments, the solvent may include at least one of ether, alcohol, glycolether, an aromatic hydrocarbon compound, ketone, and ester. For example, the solvent may be selected from ethylene glycol monomethyl ether, ethylene glycol monoethyl ether, 2-methoxyethyl acetate (methyl cellosolve acetate), 2-ethoxyethyl acetate (ethyl cellosolve acetate), diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methylethylketone, cyclopentanone, cyclohexanone, ethyl 2-hydroxypropionate, ethyl 2-hydroxy-2-methylpropionate, ethyl ethoxy acetate, ethyl hydroxy acetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactoate, and butyl lactoate. The solvents may be used alone or in combination of at least two thereof. In some implementations, the photoresist composition includes about 20% to about 95% by weight of the solvent based on the total weight of the photoresist composition In some implementations, the amount of the solvent in the photoresist composition may be adjusted so that a solid content of the photoresist composition may be in a range of about 3% to about 20% by weight.

The photoresist composition may further include a basic quencher. The basic quencher may trap some acids generated in an exposed area of a photoresist film obtained from the photoresist composition. In some implementations, the basic quencher may be included in the photoresist composition and improve exposure sensitivity and contrast when a partial region of the photoresist film obtained from the photoresist composition is exposed.

In some implementations, the basic quencher may include primary aliphatic amine, secondary aliphatic amine, tertiary aliphatic amine, aromatic amine, heterocyclic ring-containing amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, amides, imides, carbamates, or ammonium salts. For example, the basic quencher may include triethanol amine, triethyl amine, tributyl amine, tripropyl amine, hexamethyl disilazane, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or a combination thereof but is not limited thereto.

In some implementations, the photoresist composition includes about 0.01% to about 5.0% by weight of the basic quencher based on the total weight of the photosensitive polymer, without being limited thereto.

The photoresist composition may further include a photobase generator.

The photobase generator may generate a base by absorbing active energy rays due to light irradiation to decompose a chemical structure of the photobase generator. A constituent material of the photobase generator is not specifically limited and may be any material capable of generating a base due to light irradiation.

In some implementations, the photobase generator may include a nonionic photobase generator. In some implementations, the photobase generator may include an ionic photobase generator. The base generated by the photobase generator due to light irradiation may trap part of the acid generated in the exposed area of the photoresist film obtained from the photoresist composition. In some implementations, the photobase generator may be included in the photoresist composition and improve exposure sensitivity and contrast when a partial region of the photoresist film obtained from the photoresist composition is exposed.

In some implementations, the photobase generator may include a carbamate compound, an α-aminoketone compound, a quaternary ammonium compound, an aminocyclopropenone compound, an O-acyloxime compound, or 2-(9-oxoxanthen-2-yl) propionic acid 1,5,7-triazabicyclo[4.4.0]dec-5-ene salt.

Examples of the photobase generator including the carbamate compound may include 1-(2-anthraquinonyl) ethyl 1-piperidinecarboxylate, 1-(2-anthraquinonyl)ethyl 1H-2-ethylimidazole-1-carboxylate, 9-anthrylmethyl N,N-diethylcarbamate, 9-anthrylmethyl 1H-imidazole-1-carboxylate, bis[1-(2-anthraquinonyl)ethyl]1,6-hexanediylbiscarbamate, and bis(9-anthrylmethyl) 1,6-hexanediylbiscarbamate.

Examples of the photobase generator including the α-aminoketone compound may include 1-phenyl-2-(4-morpholinobenzoyl)-2-dimethylaminobutane, and 2-(4-methylthiobenzoyl)-2-morpholino propane.

Examples of the photobase generator including the quaternary ammonium compound may include 1-(4-phenylthiophenacyl)-1-azonia-4-azabicyclo[2,2,2]octane tetraphenylborate, 5-(4-phenylthiophenacyl)-1-aza-5-azoniabicyclo[4,3,0]-5-nonene tetraphenylborate, and 8-(4-phenylthiophenacyl)-1-aza-8-azoniabicyclo[5,4,0]-7-undecene tetraphenylborate.

Examples of the photobase generator including the aminocyclopropenone compound may include 2-diethylamino-3-phenylcyclopropenone, 2-diethylamino-3-(1-naphthyl)cyclopropenone, 2-pyrrolidinyl-3-phenylcyclopropenone, 2-imidazolyl-3-phenylcyclopropenone, and 2-isopropylamino-3-phenylcyclopropenone.

In some implementations, the photobase generator may be selected from 5-benzyl-1,5-diazabicyclo[4.3.0]nonane, 5-(anthracen-9-yl-methyl)-1,5-diaza[4.3.0]nonane, 5-(2′-nitrobenzyl)-1,5-diazabicyclo [4.3.0]nonane, 5-(4′-cyanobenzyl)-1,5-diazabicyclo[4.3.0]nonane, 5-(3′-cyanobenzyl)-1,5-diazabicyclo[4.3.0]nonane, 5-(anthraquinon-2-yl-methyl)-1,5-diaza[4.3.0]nonane, 5-(2′-chlorobenzyl)-1,5-diazabicyclo[4.3.0]nonane, 5-(4′-methylbenzyl)-1,5-diazabicyclo [4.3.0]nonane, 5-(2′,4′,6′-trimethylbenzyl)-1,5-diazabicyclo[4.3.0]nonane, 5-(4′-ethenylbenzyl)-1,5-diazabicyclo[4.3.0]nonane, 5-(3′-trimethylbenzyl)-1,5-diazabicyclo [4.3.0]nonane, 5-(2′,3′-dichlorobenzyl)-1,5-diazabicyclo[4.3.0]nonane, 5-(naphth-2-yl-methyl-1,5-diazabicyclo[4.3.0]nonane, 1,4-bis(1,5-diazabicyclo[4.3.0]nonanylmethyl)benzene, 8-benzyl-1,8-diazabicyclo[5.4.0]undecane, 8-benzyl-6-methyl-1,8-diazabicyclo[5.4.0]undecane, 9-benzyl-1,9-diazabicyclo[6.4.0]dodecane, 10-benzyl-8-methyl-10-diazabicyclo[7.4.0]tridecane, 11-benzyl-1,11-diazabicyclo[8.4.0]tetradecane, 8-(2′-chlorobenzyl)-1,8-diazabicyclo[5.4.0]undecane, 8-(2′,6′-dichlorobenzyl)-1,8-diazabicyclo[5.4.0]undecane, 4-(diazabicyclo[4.3.0]nonanylmethyl)-1,1′-biphenyl, 4,4′-bis(diazabicyclo[4.3.0]nonanylmethyl)-11′-biphenyl, 5-benzyl-2-methyl-1,5-diazabicyclo[4.3.0]nonane, 5-benzyl-7-methyl-1,5,7-triazabicyclo[4.4.0]decane, and a combination thereof.

In the photoresist composition, the photobase generator may be used alone or in combination of at least two thereof. In some implementations, the photoresist composition includes about 0.1% to about 30% by weight of the photobase generator based on the total weight of the photosensitive polymer, without being limited thereto.

In some implementations, the photoresist composition may further include at least one of a surfactant, a dispersant, a desiccant, and a coupling agent.

In some implementations, the surfactant may improve the coating uniformity and wettability of the photoresist composition. In some implementations, the surfactant may include sulfuric acid ester salts, sulfonates, phosphate ester, soap, amine salts, quaternary ammonium salts, polyethylene glycol, alkylphenol ethylene oxide adducts, polyhydric alcohol, a nitrogen-containing vinyl polymer, or a combination thereof, without being limited thereto. For example, the surfactant may include alkylbenzene sulfonates, alkylpyridinium salts, polyethylene glycol, or quaternary ammonium salts. When the photoresist composition includes the surfactant, the of the photoresist composition may include about 0.001% to about 3% by weight of the surfactant based on the total weight of the photoresist composition.

In some implementations, the dispersant may uniformly disperse respective components in the photoresist composition. In some implementations, the dispersant may include an epoxy resin, polyvinyl alcohol, polyvinyl butyral, polyvinyl pyrrolidone, glucose, sodium dodecyl sulfate, sodium citrate, oleic acid, linoleic acid, or a combination thereof, without being limited thereto. When the photoresist composition includes the dispersant, the photoresist composition may include about 0.001% to about 5% by weight of the dispersant based on the total weight of the photoresist composition.

In some implementations, the desiccant may prevent adverse effects due to moisture in the photoresist composition. In some implementations, the desiccant may include polyoxyethylene nonylphenolether, polyethylene glycol, polypropylene glycol, polyacrylamide, or a combination thereof, without being limited thereto. When the photoresist composition includes the desiccant, photoresist composition may include about 0.001% to about 10% by weight of the dessicant based on the total weight of the photoresist composition.

In some implementations, the coupling agent may increase adhesion of the photoresist composition with a lower film when the lower film is coated with the photoresist composition. In some implementations, the coupling agent may include a silane coupling agent. The silane coupling agent may include vinyl trimethoxysilane, vinyl triethoxysilane, vinyl trichlorosilane, vinyl tris(β-methoxyethoxy)silane, 3-methacryl oxypropyl trimethoxysilane, 3-acryl oxypropyl trimethoxysilane, p-styryl trimethoxysilane, 3-methacryl oxypropyl methyldimethoxysilane, 3-methacryl oxypropyl methyldiethoxysilane, or trimethoxy[3-(phenylamino)propyl]silane, without being limited thereto. When the photoresist composition includes the coupling agent, the photoresist composition may include about 0.001% to about 5% by weight of the coupling agent based on the total weight of the photoresist composition.

In general, a vast amount of research has been conducted into an EUV lithography technique incorporating an exposure process using EUV light having a very short wavelength of 13.5 nm as an advanced technique for superseding a lithography process using a KrF excimer laser (248 nm) and an ArF excimer laser (193 nm). An EUV lithography process may be based on a different action mechanism from the lithography process using the KrF excimer laser and the ArF excimer laser. In the EUV lithography process, when a typical photosensitive polymer having an ionic polarity inversion group is used as a material for a photoresist composition, the ionic polarity inversion group may be photo-decomposed by exposure, thus causing a difference in solubility in a developer. However, a process of synthesizing the typical photosensitive polymer including the ionic polarity inversion group may be comparatively complicated, and a repeating unit including the ionic polarity inversion group may have a comparatively low solubility in organic solvents. Accordingly, in a typical photoresist composition including the typical photosensitive polymer having the ionic polarity inversion group, precipitation of the repeating unit including the ionic polarity inversion group may likely occur. Therefore, the typical photoresist composition may be disadvantageous in terms of storage stability. In addition, defects may occur due to the precipitate when a photolithography process is performed by using the typical photoresist composition.

A photosensitive polymer according to embodiments may include a first repeating unit having a nonionic polarity inversion group as shown in Formula 1. In some implementations, because the photosensitive polymer according to the embodiment does not include an ionic material unlike the typical photosensitive polymer having the ionic polarity inversion group, problems caused when the typical photosensitive polymer having the ionic polarity inversion group is used may be solved. When a partial region of a photoresist film obtained from a nonionic non-chemically amplified photoresist composition including the photosensitive polymer is exposed, secondary electrons may be generated from the second repeating unit in an exposed area of the photoresist film, and a polarity of the first repeating unit may be inversed due to the generated secondary electrons. Thus, a polarity of the photosensitive polymer may be changed. Accordingly, in a photoresist film obtained from a photoresist composition described herein, a dissolution contrast for a developer between an exposed area and a non-exposed area may be maximized, and thus, a line edge roughness (LER) and a line width roughness (LWR) may be reduced. As a result, a high pattern fidelity may be achieved. By manufacturing an integrated circuit (IC) device using a photoresist composition described herein, the dimensional precision of a pattern required for the IC device may be improved and the productivity of a process of manufacturing the IC device may be increased.

### SYNTHESIS EXAMPLE 1 (SYNTHESIS OF COPOLYMER)

A copolymer was synthesized according to Reaction Scheme 1:

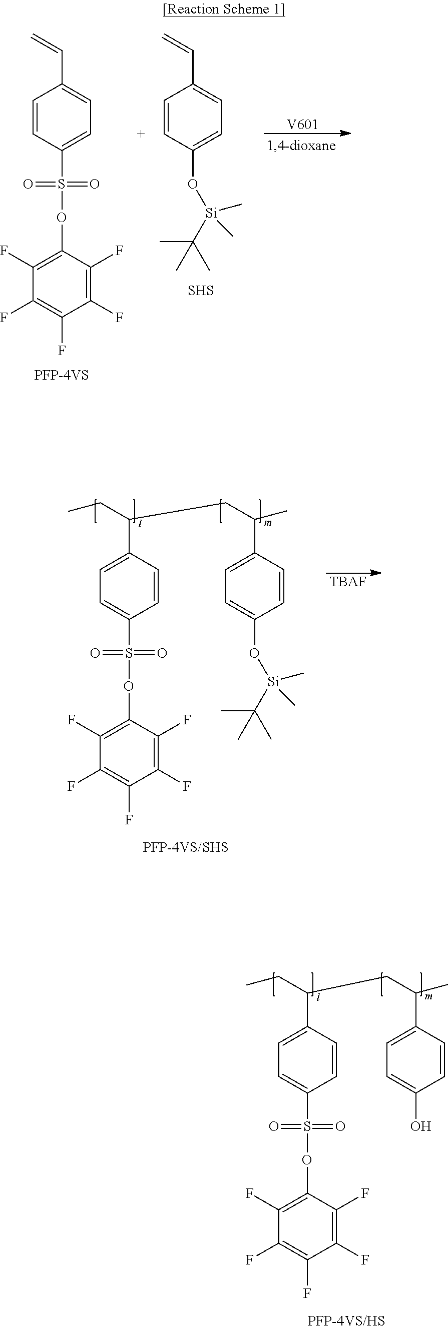

A process of Reaction Scheme 1 is now described in detail. 1.6 g of perfluorophenyl 4-vinylbenzenesulfonate (PFP-4VS), 2.4 g of p-(t-butyldimethylsiloxy)styrene (SHS) and 0.1 g of V601(C₁₀H₁₈N₂O₂, CAS No. 2589-57-3) were dissolved in 30 mL of 1,4-dioxane and reacted at a temperature of 80° C. for 4 hours. 31.4 mL of a tetra-n-butylammonium fluoride (TBAF) solution (1M in tetrahydrofuran) and 2.3 g of acetic acid were added to the obtained reaction product and further reacted at room temperature for 12 hours. After the reaction was completed, 24 mL of distilled water was added, and extraction was performed with ethylacetate. Organic layers were collected and distilled under reduced pressure, and then a precipitate was obtained using n-hexane. The obtained solid was dried at a temperature of 40° C. for 24 hours to synthesize a copolymer (PFP-4VS/HS).

¹H-NMR (500 MHz, DMSO-d6) δ8 8.8-9.3 ppm (phenolic hydroxyl group), 6.1-8.1 ppm (phenolic hydrogen).

### SYNTHESIS EXAMPLE 2 (SYNTHESIS OF TERPOLYMER)

A terpolymer was synthesized according to Reaction Scheme 2:

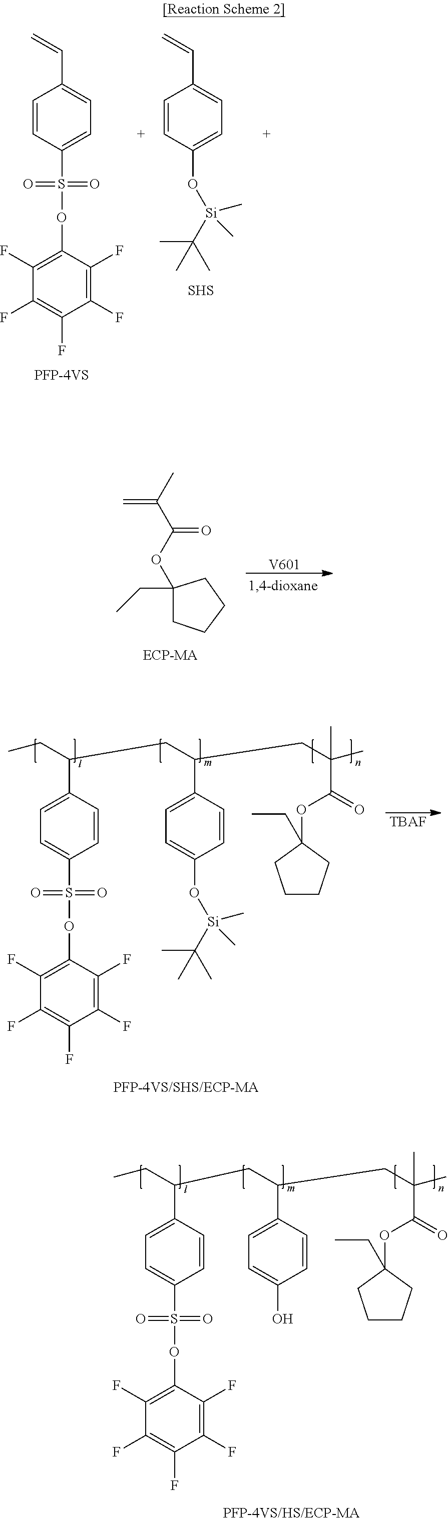

A process of Reaction Scheme 2 is now described in detail. 0.9 g of PFP-4VS, 1.5 g of SHS, 2.2 g of ethylcyclopentyl methacrylate (ECP-MA), and 0.9 g of V601 were dissolved in 24 mL of 1,4-dioxane and reacted at a temperature of 80° C. for 4 hours. 19.6 mL of a TBAF solution (1M in tetrahydrofuran) and 1.4 g of acetic acid were added to the obtained reaction product and further reacted at room temperature for 12 hours. After the reaction was completed, 50 mL of distilled water was added, and extraction was performed with ethylacetate. Organic layers were collected and distilled under reduced pressure, and then a precipitate was obtained using n-hexane. The obtained solid was dried at a temperature of 40° C. for 24 hours to synthesize a terpolymer (PFP-4VS/HS/ECP-MA).

¹H-NMR (500 MHz, DMSO-d6) δ8 8.8-9.3 ppm (phenolic hydroxyl group), 6.1-8.1 ppm (phenolic hydrogen), 0.0-1.1 ppm, (alkyl group)

### Manufacture of IC Device

Next, a specific example of a method of manufacturing an IC device by using a photoresist composition according to the inventive concept is described.

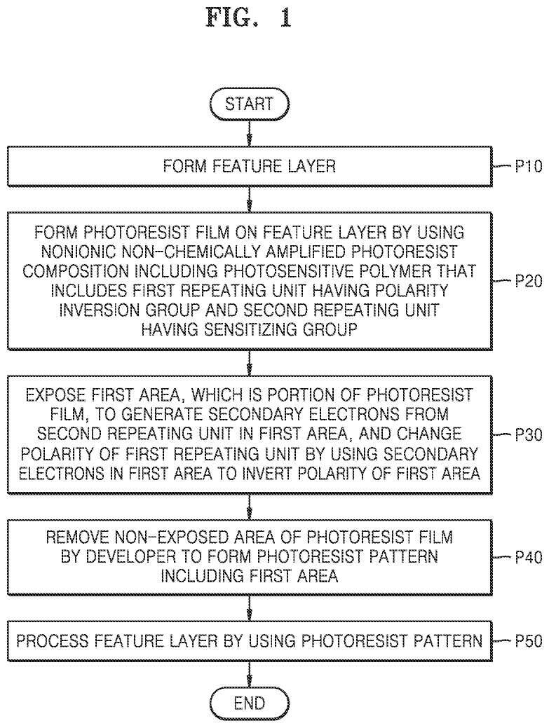

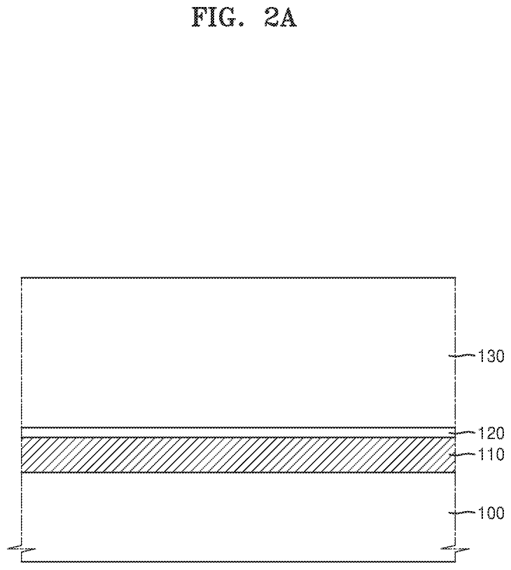

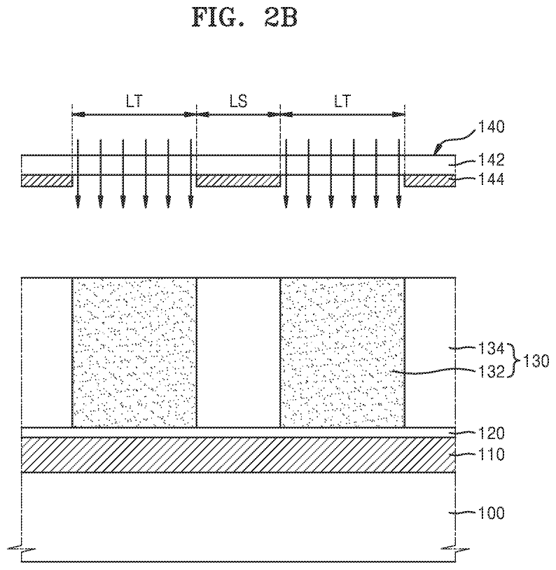

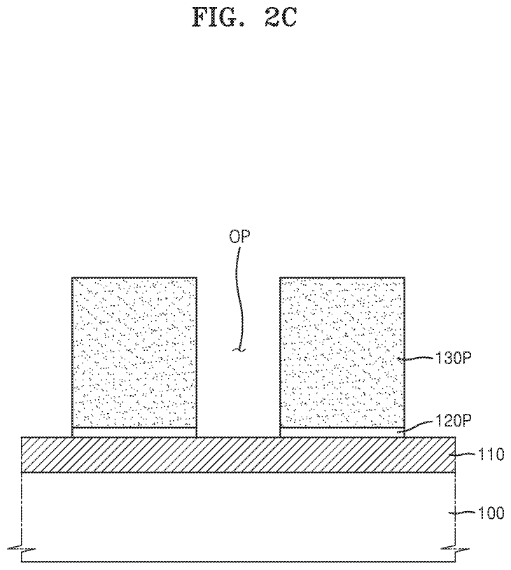

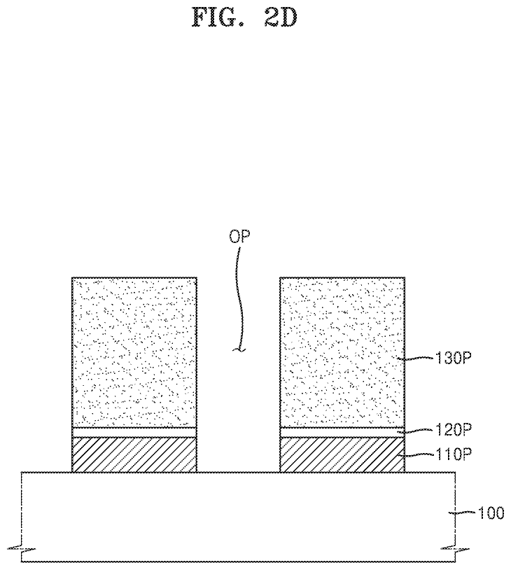

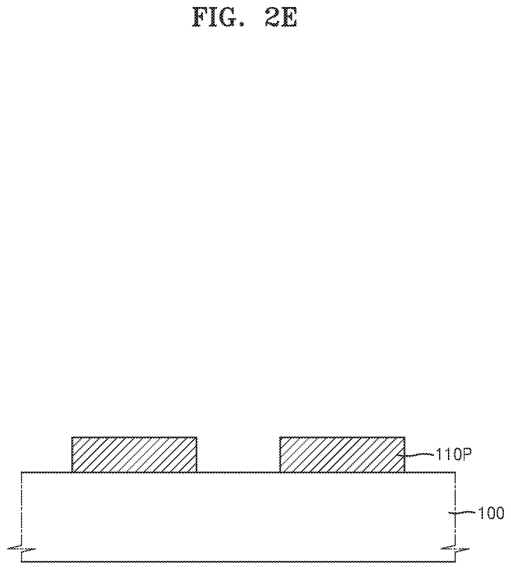

FIG. 1 is a flowchart of a method of manufacturing an IC device. FIGS. 2A to 2E are cross-sectional views of a process sequence of a method of manufacturing an IC device.

Referring to FIGS. 1 and 2A, a feature layer 110 may be formed on a substrate 100 in process P10, and a photoresist film 130 may be formed on the feature layer 110 by using the photoresist composition according to the inventive concept in process P20.

The photoresist film 130 may include a nonionic non-chemically amplified photoresist composition including a photosensitive polymer, which includes a first repeating unit having a polarity inversion group and a second repeating unit having a sensitizing group. The photoresist film 130 may include main components of the photoresist composition described herein. The photosensitive polymer included in the photoresist film 130 may include the first repeating unit represented by Formula 1 and the second repeating unit. In some implementations, photosensitive polymer included in the photoresist film 130 may further include a third repeating unit of Formula 4. Details of each of Formulas 1 and 4 may be understood with reference to the descriptions herein. Details of the photoresist composition may be the same as those described above.

The substrate 100 may include a semiconductor substrate. The feature layer 110 may include an insulating film, a conductive film, or a semiconductor film. For example, the feature layer 110 may include a metal, an alloy, a metal carbide, a metal nitride, a metal oxynitride, a metal oxycarbide, a semiconductor, polysilicon, oxide, a nitride, oxynitride, or a combination thereof, without being limited thereto.

In some implementations, as shown in FIG. 2A, before the photoresist film 130 is formed on the feature layer 110, a lower film 120 may be formed on the feature layer 110. In this case, the photoresist film 130 may be formed on the lower film 120. The lower film 120 may prevent the photoresist film 130 from being adversely affected by the feature layer 110 located thereunder. In some implementations, the lower film 120 may include an organic or inorganic anti-reflective coating (ARC) material for a krypton fluoride (KrF) excimer laser, an argon fluoride (ArF) excimer laser, an extreme ultraviolet (EUV) laser, or any other light source. In some implementations, the lower film 120 may include a bottom anti-reflective coating (BARC) film or a developable bottom anti-reflective coating (DBARC) film. In some implementations, the lower film 120 may include an organic component having a light-absorbing structure. The light-absorbing structure may include, for example, at least one benzene ring or a hydrocarbon compound in which benzene rings are fused. The lower film 120 may be formed to a thickness of about 1 nm to about 100 nm, without being limited thereto. In some implementations, the lower film 120 may be omitted.

To form the photoresist film 130, the lower film 120 may be coated with a photoresist composition, and the photoresist composition may be then annealed. The coating process may be performed using a method, such as a spin coating process, a spray coating process, or a dip coating process. The process of annealing the photoresist composition may be performed at a temperature of about 80° C. to about 300° C. for about 10 seconds to about 100 seconds, without being limited thereto. A thickness of the photoresist film 130 may be several tens of times to several hundred times a thickness of the lower film 120. The photoresist film 130 may be formed to a thickness of about 10 nm to about 1 μm, without being limited thereto.

Referring to FIGS. 1 and 2B, in process P30, a first area 132, which is a portion of the photoresist film 130, may be exposed, and thus, secondary electrons may be generated from the second repeating unit indicated by “m” in Formula 1 in the first area 132. A polarity of the first repeating unit indicated by “1” in Formula 1 may be changed by using the secondary electrons in the first area 132, and thus, a polarity of the first area 132 may be inversed. Due to the exposure process according to process P30, a polarity of the first repeating unit indicated by “1” may be changed to hydrophilicity, and a polarity of the first area 132 may be inversed to hydrophilicity. Accordingly, the difference in solubility in the hydrophobic developer between the exposed first area 132 and the non-exposed second area 134 of the photoresist film 130 may increase.

When a photobase generator is included in the photoresist composition used to form the photoresist film 130, due to the exposure process according to process P30, a base may be generated from the photobase generator in the first area 132, while a base may not be generated from the photobase generator in the non-exposed second area 134. In the first area 132, excess acid may be neutralized by a reaction of the base generated by the photobase generator with an acid.

In some implementations, to expose the first area 132 of the photoresist film 130, a photomask 140 having a plurality of light-shielding areas LS and a plurality of light-transmitting areas LT may be arranged at a predetermined position on the photoresist film 130, and the first area 132 of the photoresist film 130 may be exposed through the plurality of light-transmitting areas LT of the photomask 140. The first area 132 of the photoresist film 130 may be exposed using a KrF excimer laser (248 nm), an ArF excimer laser (193 nm), a fluorine (F₂) excimer laser (157 nm), or an EUV laser (13.5 nm).

The photomask 140 may include a transparent substrate 142 and a plurality of light-shielding patterns 144 formed on the transparent substrate 142 in the plurality of light-shielding areas LS. The transparent substrate 142 may include quartz. The plurality of light-shielding patterns 144 may include chromium (Cr). The plurality of light-transmitting areas LT may be defined by the plurality of light-shielding patterns 144. According to the inventive concept, a reflective photomask (not shown) for EUV exposure may be used instead of the photomask 140 to expose the first area 132 of the photoresist film 130.

After the first area 132 of the photoresist film 130 is exposed according to process P30 of FIG. 1, the photoresist film 130 may be annealed. The annealing process may be performed at a temperature of about 50° C. to about 400° C. for about 10 seconds to about 100 seconds, without being limited thereto.

Referring to FIGS. 1 and 2C, in process P40, the photoresist film 130 may be developed using a developer to remove the second area 134 of the photoresist film 130, which is not exposed. As a result, a photoresist pattern 130P including the first area 132 of the photoresist film 130, which is exposed, may be formed.

The photoresist pattern 130P may include a plurality of openings OP. After the photoresist pattern 130P is formed, portions of the lower film 120, which are exposed through the plurality of openings OP, may be removed to form a lower pattern 120P.

In some implementations, the developing of the photoresist film 130 may be performed using a negative-tone development (NTD) process. In this case, an organic developer using an organic solvent may be used as the developer. The organic developer may include a ketone solvent, such as 2-hexanone and 2-heptanone; a glycol ether ester solvent, such as propylene glycol monomethyl ether acetate; an ester solvent, such as butyl acetate; a glycol ether solvent, such as propylene glycol monomethyl ether; an amide solvent, such as N,N-dimethyl acetamide; or an aromatic hydrocarbon solvent, such as anisole. In this case, normal-butyl acetate (or n-butyl acetate) or 2-heptanone may be used as the organic developer, but the kind of the developer is not limited thereto.

As described with reference to FIG. 2B, the difference in solubility in the developer between the first area 132 of the photoresist film 130, which is exposed, and the second area 134 of the photoresist film 130, which is not exposed, may be increased. Thus, the first area 132 may not be removed but remain intact while the second area 134 is being removed by developing the photoresist film 130 during the process of FIG. 2C. Accordingly, after the photoresist film 130 is developed, residue defects, such as a footing phenomenon, may not occur and the photoresist pattern 130P may obtain a vertical sidewall profile. As described above, by improving a profile of the photoresist pattern 130P, when the feature layer 110 is processed using the photoresist pattern 130P, a CD of an intended processing region may be precisely controlled in the feature layer 110.

Referring to FIGS. 1 and 2D, in process P50, the feature layer 110 may be processed using the photoresist pattern 130P in the resultant structure of FIG. 2C.

To process the feature layer 110, various processes, such as a process of etching the feature layer 110 exposed by the openings OP of the photoresist pattern 130P, a process of implanting impurity ions into the feature layer 110, a process of forming an additional film on the feature layer 110 through the openings OP, and a process of modifying portions of the feature layer 110 through the openings OP, may be performed. FIG. 2D illustrates a process of forming a feature pattern 110P by etching the feature layer 110, which is exposed by the openings OP, as an example of processing the feature layer 110.

In some implementations, the process of forming the feature layer 110 may be omitted from the process described with reference to FIG. 2A. In this case, the substrate 100 may be processed using the photoresist pattern 130P instead of the process described with reference to process P50 of FIG. 1 and FIG. 2D. For example, various processes, such as a process of etching a portion of the substrate 100 using the photoresist pattern 130P, a process of implanting impurity ions into a partial region of the substrate 100, a process of forming an additional film on the substrate 100 through the openings OP, and a process of modifying portions of the substrate 100 through the openings OP, may be performed.

Referring to FIG. 2E, the photoresist pattern 130P and the lower pattern 120P, which remain on the feature pattern 110P, may be removed from the resultant structure of FIG. 2D. The photoresist pattern 130P and the lower pattern 120P may be removed using an ashing process and a strip process.

In the method of manufacturing the IC device with reference to FIGS. 1 and 2A to 2E, the difference in acidity between the exposed area and the non-exposed area may be increased to increase solubility in the developer between the exposed area and the non-exposed area of the photoresist film 130 obtained using a photoresist composition described herein. Thus, an LER and an LWR may be reduced in the photoresist pattern 130P obtained from the photoresist film 130 to provide a high pattern fidelity. Accordingly, when a subsequent process is performed on the feature layer 110 and/or the substrate 100 using the photoresist pattern 130P, dimensional precision may be improved by precisely controlling critical dimensions of processing regions or patterns to be formed on the feature layer 110 and/or the substrate 100. In addition, the CD distribution of patterns to be formed on the substrate 100 may be uniformly controlled and the productivity of a process of manufacturing an IC device may be increased.

While the present disclosure has been particularly shown and described with reference to implementations thereof, it will be understood that various changes in form and details may be made therein without departing from the spirit and scope of the following claims.

What is claimed is:

1. A nonionic non-chemically amplified photoresist composition comprising a photosensitive polymer comprising repeating units represented by Formula 1:
[Formula 1] [symbol]
wherein each of R¹ and R⁴ is independently a hydrogen (H) atom, a substituted or unsubstituted C1-C10 linear or branched alkyl group, a substituted or unsubstituted C2-C10 linear or branched alkenyl group, a substituted or unsubstituted C2-C10 linear or branched alkynyl group, a substituted or unsubstituted C1-C3 alkoxy group, a C6-C18 aryl group, a C6-C18 cycloalkyl group, or a C6-C18 arylalkyl group;
R² is a direct bond, a C1-C10 alkylene group, a C1-C10 halogenated alkylene group, a C2-C10 alkenyl group, a C2-C10 halogenated alkenyl group, a C2-C10 alkynyl group, a C2-C10 halogenated alkynyl group, a C3-C20 cycloalkylene group, a C6-C20 arylene group, a C6-C20 halogenated arylene group, a C7-C20 arylalkylene group, or a C7-C20 alkylarylene group;
R³ is an unsubstituted C1-C10 linear or branched alkyl group, a C1-C10 linear or branched alkyl group substituted with a fluorine atom, an unsubstituted C2-C10 linear or branched alkenyl group, a C2-C10 linear or branched alkenyl group substituted with a fluorine atom, an unsubstituted C2-C10 linear or branched alkynyl group, a C2-C10 linear or branched alkynyl group substituted with a fluorine atom, an unsubstituted C6-C20 aryl group, a C6-C20 aryl group substituted with a fluorine atom, an unsubstituted C7-C20 arylalkyl group, a C7-C20 arylalkyl group substituted with a fluorine atom, an unsubstituted C7-C20 alkylaryl group, or a C7-C20 alkylaryl group substituted with a fluorine atom;
R⁵ is a C6-C30 aryl group substituted with at least one of a hydroxy group and a C1-C5 alkoxy group, and
1/(1+m) and m/(1+m) are each in a range of from 0.05 to 0.95.

2. The photoresist composition of claim 1, wherein R³ is an aryl group comprising an electron withdrawing group,
wherein the electron withdrawing group is selected from a fluorine (F) atom, a chlorine (Cl) atom, a bromine (Br) atom, an iodine (I) atom, a heterocyclic group including sulfur (S), a heterocyclic group including nitrogen (N), a nitro group (—NO₂), a trifluoro methyl group (—CF₃), a pentafluoro ethyl group (—C₂F₅), a trifluoromethyl sulfonyl group (—SO₂CF₃), a pentafluoroethyl sulfonyl group (—SO₂C₂F₅), an acetyl group (—COCH₃), an aldehyde group (—CHO), a ketone group (—C(═O)—), a carboxyl group (—CO₂H), an ester group (—CO₂R), and cyano (CN); and
R is a C1-C10 alkyl group.

3. The photoresist composition of claim 1, wherein R³ has a structure represented by Formula 2:
[Formula 2] [symbol]
wherein each of R³¹, R³², R³³, R³⁴, and R³⁵ is independently a hydrogen (H) atom, a fluorine (F) atom, a linear or branched C1-C10 perfluoroalkyl group, a linear or branched C2-C10 perfluoroalkenyl group, or a linear or branched C2-C10 perfluoroalkynyl group,
at least two of R³¹, R³², R³³, R³⁴, and R³⁵ are the same, and
R³⁶ is a C1-C10 perfluoroalkylene group.

4. The photoresist composition of claim 1, wherein R³ is selected from the following structures: [symbol]
wherein * is a linking site.

5. The photoresist composition of claim 1, wherein R² is selected from the following structures: [symbol]
wherein * is a linking site.

6. The photoresist composition of claim 1, wherein R⁵ comprises a phenyl group, a naphthyl group, an anthracenyl group, or a pyridinyl group.

7. The photoresist composition of claim 1, wherein R⁵ is selected from Formula 3-1, Formula 3-2, Formula 3-3, Formula 3-4, and Formula 3-5:
[Formula 3-1] [symbol]
[Formula 3-2] [symbol]
[Formula 3-3] [symbol]
[Formula 3-4] [symbol]
[Formula 3-5] [symbol]
wherein each of R⁵¹, R⁵², R⁵³, R⁵⁴, and R⁵⁵ is a hydroxy group or a C1-C5 alkoxy group, p1 P1 is an integer of 1 to 5,
P2 is an integer of 1 to 7,
P3 is an integer of 1 to 9,
P4 is an integer of 1 to 6,
P5 is an integer of 1 to 7, and
* is a linking site.

8. The photoresist composition of claim 1, wherein R⁵ is selected from the following structures: [symbol] [symbol]
wherein * is a linking site.

9. The photoresist composition of claim 1, wherein the photosensitive polymer further comprises a repeating unit represented by Formula 4:
[Formula 4] [symbol]
wherein R⁶ is a hydrogen atom, a substituted or unsubstituted C1-C10 linear or branched alkyl group, a substituted or unsubstituted C2-C10 linear or branched alkenyl group, a substituted or unsubstituted C2-C10 linear or branched alkynyl group, a C1-C3 alkoxy group, a C6-C18 aryl group, a C6-C18 cycloalkyl group, or a C6-C18 arylalkyl group;
R⁷ is a substituted or unsubstituted C1-C10 linear or branched alkyl group, a substituted or unsubstituted C2-C10 linear or branched alkenyl group, a substituted or unsubstituted C2-C10 linear or branched alkynyl group, a substituted or unsubstituted C3-C30 alicyclic group, a substituted or unsubstituted C6-C20 aryl group, a substituted or unsubstituted C2-C20 heteroaryl group, a substituted or unsubstituted C7-C20 arylalkyl group, a substituted or unsubstituted C7-C20 alkylaryl group, or a substituted or unsubstituted C2-C20 heteroarylalkyl group; and
* is a linking site.

10. The photoresist composition of claim 9, wherein R⁷ comprises a hydroxy-containing alicyclic moiety.

11. The photoresist composition of claim 9, wherein R⁷ is selected from the following structures: [symbol]
wherein p is an integer of 1 to 10 and * is a linking site.

12. The photoresist composition of claim 1, wherein the photoresist composition does not comprise a photoacid generator (PAG).

13. The photoresist composition of claim 1, further comprising a basic quencher.

14. The photoresist composition of claim 1, further comprising a photobase generator.

15. A method of manufacturing an integrated circuit device, the method comprising:
forming a photoresist film on a feature layer by using a nonionic non-chemically amplified photoresist composition comprising a photosensitive polymer, the photosensitive polymer comprising a first repeating unit having a polarity inversion group and a second repeating unit having a sensitizing group;
exposing a first area of the photoresist film to generate secondary electrons from the second repeating unit in the first area and changing a polarity of the first repeating unit by using the secondary electrons in the first area to invert a polarity of the first area, wherein the first area is a portion of the photoresist film;
removing a non-exposed area of the photoresist film by using a developer to form a photoresist pattern, the photoresist pattern comprising the first area; and
processing the feature layer by using the photoresist pattern.

16. The method of claim 15, wherein the photosensitive polymer comprises repeating units represented by Formula 1:
[Formula 1] [symbol]
wherein each of R¹ and R⁴ is independently a hydrogen atom, a substituted or unsubstituted C1-C10 linear or branched alkyl group, a substituted or unsubstituted C2-C10 linear or branched alkenyl group, a substituted or unsubstituted C2-C10 linear or branched alkynyl group, a substituted or unsubstituted C1-C3 alkoxy group, a C6-C18 aryl group, a C6-C18 cycloalkyl group, or a C6-C18 arylalkyl group;
R² is a direct bond, a C1-C10 alkylene group, a C1-C10 halogenated alkylene group, a C2-C10 alkenyl group, a C2-C10 halogenated alkenyl group, a C2-C10 alkynyl group, a C2-C10 halogenated alkynyl group, a C3-C20 cycloalkylene group, a C6-C20 arylene group, a C6-C20 halogenated arylene group, a C7-C20 arylalkylene group, or a C7-C20 alkylarylene group;
R³ is an unsubstituted C1-C10 linear or branched alkyl group, a C1-C10 linear or branched alkyl group substituted with a fluorine atom, an unsubstituted C2-C10 linear or branched alkenyl group, a C2-C10 linear or branched alkenyl group substituted with a fluorine atom, an unsubstituted C2-C10 linear or branched alkynyl group, a C2-C10 linear or branched alkynyl group substituted with a fluorine atom, an unsubstituted C6-C20 aryl group, a C6-C20 aryl group substituted with a fluorine atom, an unsubstituted C7-C20 arylalkyl group, a C7-C20 arylalkyl group substituted with a fluorine atom, an unsubstituted C7-C20 alkylaryl group, or a C7-C20 alkylaryl group substituted with a fluorine atom;
R⁵ is a C6-C30 aryl group substituted with at least one of a hydroxy group and a C1-C5 alkoxy group; and
each of 1/(1+m) and m/(1+m) is in a range of 0.05 to 0.95.

17. The method of claim 16, wherein R³ has a structure represented by Formula 2:
[Formula 2] [symbol]
wherein each of R³¹, R³², R³³, R³⁴, and R³⁵ is a hydrogen (H) atom, a fluorine (F) atom, a linear or branched C1-C10 perfluoroalkyl group, a linear or branched C2-C10 perfluoroalkenyl group, or a linear or branched C2-C10 perfluoroalkynyl group,
at least two of R³¹, R³², R³³, R³⁴, and R³⁵ are the same, and
R³⁶ is a C1-C10 perfluoroalkylene group.

18. The method of claim 16, wherein R⁵ is selected from Formula 3-1, Formula 3-2, Formula 3-3, Formula 3-4, and Formula 3-5:
[Formula 3-1] [symbol]
[Formula 3-2] [symbol]
[Formula 3-3] [symbol]
[Formula 3-4] [symbol]
[Formula 3-5] [symbol]
wherein each of R⁵¹, R⁵², R⁵³, R⁵⁴, and R⁵⁵ is a hydroxy group or a C1-C5 alkoxy group,
P1 is an integer of 1 to 5,
P2 is an integer of 1 to 7,
P3 is an integer of 1 to 9,
P4 is an integer of 1 to 6,
P5 is an integer of 1 to 7, and
* is a linking site.

19. The method of claim 16, wherein the photosensitive polymer further comprises a repeating unit represented by Formula 4:
[Formula 4] [symbol]
wherein R⁶ is a hydrogen atom, a substituted or unsubstituted C1-C10 linear or branched alkyl group, a substituted or unsubstituted C2-C10 linear or branched alkenyl group, a substituted or unsubstituted C2-C10 linear or branched alkynyl group, a C1-C3 alkoxy group, a C6-C18 aryl group, a C6-C18 cycloalkyl group, or a C6-C18 arylalkyl group;
R⁷ is a substituted or unsubstituted C1-C10 linear or branched alkyl group, a substituted or unsubstituted C2-C10 linear or branched alkenyl group, a substituted or unsubstituted C2-C10 linear or branched alkynyl group, a substituted or unsubstituted C3-C30 alicyclic group), a substituted or unsubstituted C6-C20 aryl group, a substituted or unsubstituted C2-C20 heteroaryl group, a substituted or unsubstituted C7-C20 arylalkyl group, a substituted or unsubstituted C7-C20 alkylaryl group, or a substituted or unsubstituted C2-C20 heteroarylalkyl group; and
* is a linking site.

20. The method of claim 16, wherein the photoresist composition further comprises at least one of a basic quencher and a photobase generator,
wherein the exposing of the first area of the photoresist film comprises irradiating the first area with a krypton fluoride (KrF) excimer laser (248 nm), an argon fluoride (ArF) excimer laser (193 nm), an F₂ excimer laser (157 nm), or an extreme ultraviolet (EUV) laser (13.5 nm).
